(19) United States
(12) Patent Application Publication
(10) Pub. No.: US 2014/0235014 A1
(43) Pub. Date: Aug. 21, 2014

(54) METHOD FOR MANUFACTURING A METAL-INSULATOR-SEMICONDUCTOR (MIS) STRUCTURE FOR AN ELECTROLUMINESCENT DIODE

(71) Applicant: Commissariat à l'énergie atomique et aux énergies alternatives, Paris (FR)

(72) Inventor: Ivan-Christophe Robin, Grenoble (FR)

(73) Assignee: Commissariat à l'énergie atomique et aux énergies alternatives, Paris (FR)

(21) Appl. No.: 14/133,177

(22) Filed: Dec. 18, 2013

(30) Foreign Application Priority Data
Dec. 19, 2012 (FR) 12 62305

(51) Int. Cl. H01L 21/02

(52) U.S. Cl. CPC H01L 21/02565
USPC 438/104

(57) ABSTRACT

A method for manufacturing a structure comprising a substrate made of at least one n-type semiconducting metal oxide is disclosed. In one aspect, the method comprises providing a substrate made of at least one n-type semiconducting metal oxide selected from the group consisting of: ZnO, CdO, MgO, ZnMgO, and ZnCdO, wherein the doping rate of which is less than or equal to 10¹⁸/cm³. The method further comprises depositing a layer which is 1 to 10 nm thick, made of an electrically insulating metal or metalloid oxide, having a dielectric constant which is at least equal to 4, on the first main surface of the substrate. The method further comprises annealing of the electrically insulating metal or metalloid oxide layer in an oxygen atmosphere. The method further comprises depositing at least one layer made of an electrically conductive material on the electrically insulating metal or metalloid oxide layer.

### TECHNICAL FIELD

The invention relates to a method for manufacturing a structure, notably a structure of the Metal-Insulator-Semiconductor, or MIS, type, in particular for a light-emitting diode.

More specifically, the invention relates to a method for manufacturing a structure comprising a semiconducting substrate made of an oxide of at least one n-type semiconducting metal, wherein a first face of the semiconducting substrate made of ZnO is covered with a layer of an electrically insulating material, and wherein the layer of electrically insulating material is covered with at least one layer of an electrically conductive material such as a metal.

The invention notably finds application in the production of light-emitting diodes, or LEDs.

Many light devices are based on such diodes, such as screens, projectors, video walls, etc.

These diodes can also be used in devices for disinfecting water by irradiation with ultraviolet light.

The invention also finds application in the production of field-effect transistors, or FETs.

### STATE OF THE PRIOR ART

A light-emitting diode or LED is an electronic component capable of emitting light when an electric current traverses it. There are LEDs which emit a white light and LEDs which emit a coloured light, or alternatively an infrared light, or else an ultraviolet (UV) light.

More precisely, a light-emitting diode is a p-n junction in a semiconducting material. When this p-n junction is forward-biased, the recombination of the electrons and of the holes in the diode's semiconducting material causes photons to be emitted.

Most of the recombinations are radiative, and the emitting face of the LED is located on the side of the P zone, since it is the more radiative of the zones.

Large-gap II-V semiconductors (with wide forbidden bands) made of nitrides such as GaN, GaAlN, AlN or InN, currently constitute the family of semiconductors which is most promising for the production of solid sources of lights in the visible and UV spectra.

High-power LEDs [1, 2], and even short-wavelength lasers [3, 4], have been produced with these semiconductors made of nitrides.

It is possible to manufacture these components with the family of nitride semiconductors, since p-doping of GaN and GaInN was successfully achieved at the start of the 1990s using magnesium as the dopant [5].

However, a problem which continues to be posed with nitride semiconductors, which has persisted since the 1990s, and which is becoming increasingly problematic with the use of short emission wavelengths, is the high resistivity of GaN and of AlGaN.

Indeed, the activation energy of magnesium, the dopant most commonly used in p-type GaN, is 200 meV [6], which represents several times the kBT thermal energy at ambient temperature (kB is the Boltzmann constant and T the temperature). The activation energy of the acceptors increases with the energy of the semiconductors' forbidden band, reaching 630 meV in the case of AlN [3]. Hole activation is thus very inefficient at ambient temperature for GaN, and even more difficult for AlGaN and AlN.

Materials made of ZnO are another family of interest for the emission in the ultraviolet and deep ultraviolet ranges in the solid state.

ZnO has a band gap energy of 3.37 eV at ambient temperature, high excitonic bonding energy of 60 meV, together with a high probability of efficient excitonic transitions at high temperatures [7, 8].

Compared to AlGaInN, ZnO is therefore another material with high potential for emission in the ultraviolet spectrum, due to its resistance to high-energy radiations, the availability of high-quality substrates (leading to simple LEDs geometries), and the possibility of using wet chemical etching to form mesas if other substrates are used.

In addition, by producing alloys with MgO, ZnMgO compounds may be formed with higher band gap energies, but the quantity of Mg incorporated is limited in practice due to phase separation phenomena [9, 10].

The main difficulty when manufacturing a UV emitter based entirely on ZnO remains the absence of a reliable method to obtain p-type doping of ZnO, which is necessary for the formation of p-n homojunctions [11, 12, 13, 14].

For example, TSUKAZAKI et al. studied ZnO doped with nitrogen, and produced p-i-n homojunctions over (0 0 0 1) ScAlMgO₄ [15].

RYU et al. demonstrated light-emission (LE) of heterostructures (Zn, Be)O/ZnO in which the p-type layer was doped with arsenic [16].

LIM et al. prepared a layer of ZnO doped with phosphorus in p-n homojunctions on sapphire by radiofrequency sputtering [17].

JIAO et al. described the manufacture of a pn junction ZnO LED on an Al₂O₃ substrate [18].

IP et al. demonstrated rectifying properties in the I(V) characteristic of a ZnO/ZnMgO heterojunction, in which the p-type ZnMgO was doped with phosphorus [19].

To overcome the limits of p-type doping in ZnO or, more generally, in an n-type large-gap semiconductor, structures in which the conductivity of a zone in ZnO, or in the n-type large-gap semiconductor, is inverted have recently been proposed [20, 21].

This zone, in the n-type large-gap semiconductor in which the conductivity has thus been inverted, is commonly called the inversion zone, for example the “inversion layer”.

The presence of an inversion layer in the n-type large-gap semiconductor creates a channel of accessible moving holes. It is then sufficient to inject holes into this channel to cause a current to flow in the structures described in documents [20, 21].

This zone is created using a gate.

This gate consists of a layer made of an insulating material generally between 0.5 nm and ten nanometres thick, and of a conductive layer.

The insulating material is generally chosen from among the metal oxides and metalloid oxides, and the term “gate oxide” is then used to designate it.

The quality of this gate is of prime importance if an inversion of conductivity is to be obtained in the n-type large-gap material.

Indeed, it must be possible to apply a sufficient voltage to the gate to invert the type of conductivity without the gate leaking.

If the quality of the gate's insulating material, for example the quality of the gate oxide, is not sufficient, the gate then leaks, and no zone can be inverted in the n-type semiconductor, such as ZnO.

It has previously been proposed to use dielectric materials with a high dielectric constant (“high-k” materials), such as HfO₂ or ZrO₂, to form the insulating layer in a gate to invert a zone in the ZnO [22, 23, 24, 25], in applications such as the manufacture of field-effect transistors.

However, these documents describe neither the method for manufacturing these insulating layers, nor the required thicknesses of the high-k dielectric materials, nor the nature of the conductive layer to be used to obtain a gate of satisfactory quality.

Document [26] describes the deposition of thin layers of HfO₂ which are 4 nm thick on “Silicon On Insulator”, or SOI, substrates, by an Atomic Layer Deposition, or ALD, method.

Gate structures have been obtained by using deposition of HfO₂ and ZrO₂ by Atomic Layer Deposition (ALD) on ZnO.

This deposition method takes place in a chamber in which a vacuum of less than 100 Torr is produced. A device to regulate the temperature enables the temperature of the sample to be maintained during deposition, between ambient temperature and at least 500° C. This method consists in sending, alternatively, the precursors of hafnium or of zirconium such as tetrakis (dimethylamido) hafnium IV, in the case of hafnium, and tetrakis (dimethylamido) zirconium IV, in the case of zirconium, and water on the ZnO substrate, which is maintained at a certain temperature.

In this way, conformal layers of HfO₂ and ZrO₂ may be obtained ([26] and [27]).

It follows from the foregoing that obtaining an inversion zone in the n-type semiconductor, such as an n-type semiconducting metal oxide, is an essential condition if devices as described in documents [20, 21] are to be made to operate. For this reason very special attention must be paid to the method for preparing structures of the Electrically Conductive Material-Electrically Insulating Material-Semiconductor type, notably Metal-Insulator-Semiconductor, or “MIS”, structures, which enable such inversion to be obtained.

At the current time there is no method for depositing an electrically insulating material, such as an electrically insulating oxide such as HfO₂ or ZrO₂, on a semiconducting substrate such as a substrate made of a n-type metal oxide such as n-type ZnO, CdO, MgO, ZnMgO or ZnCdO which, after deposition of an electrically conductive material on this electrically insulating material, enables a gate to be obtained enabling the conductivity of a zone in the semiconducting substrate to be inverted efficiently, reliably and reproducibly.

There is therefore a need for such a method.

There is also a need for such a method which ensures that the gate does not leak, i.e. that it does not allow a current to pass when a voltage is applied to it, and at the highest possible voltages.

The layer of an electrically insulating material, such as an electrically insulating oxide (“gate oxide”), must typically remain a satisfactory electrical insulator for voltages of at least 10 V. In this manner, a sufficiently high electrical field may be obtained in the semiconducting substrate for the conductivity in it to be inverted.

The goal of the present invention is to provide a method for manufacturing a structure comprising a substrate made of an n-type semiconducting metal oxide, wherein a first face of the substrate is covered with a layer of an electrically insulating material, and wherein the layer of an electrically insulating material is covered with at least one layer of an electrically conductive material, said method meeting inter alia the needs listed above.

### DESCRIPTION OF THE INVENTION

This goal, and others, are achieved, in accordance with the invention, by a method for manufacturing a structure comprising a substrate made of at least one metal n-type semiconducting metal oxide, chosen from among ZnO, CdO, MgO, ZnMgO, and ZnCdO, wherein said substrate comprises a first main surface and a second main surface, wherein the first main surface of the substrate is covered with a layer made of an electrically insulating material, and the layer made of an electrically insulating material is covered with at least one layer made of an electrically conductive material, in which the following successive steps are carried out:

a) a substrate made of at least one n-type semiconducting metal oxide, chosen from among ZnO, CdO, MgO, ZnMgO, and ZnCdO, is provided, the doping rate of which is less than or equal to 10¹⁸/cm³;

b) a layer which is 1 to 10 nm thick, made of an electrically insulating metal or metalloid oxide, having a dielectric constant which is at least equal to 4, and preferably at least equal to 6, even more preferably at least equal to 7, and better still at least equal to 25, is deposited on the first main surface of the substrate;

c) annealing of the electrically insulating metal or metalloid oxide layer is accomplished in an oxygen atmosphere;

d) at least one layer made of an electrically conductive material is deposited on the electrically insulating metal or metalloid oxide layer.

The method according to the invention comprises a specific sequence of specific steps which has never been described in the prior art.

According to the invention, a substrate made of an n-type semiconducting oxide is used, which has a specific doping rate, namely an n-type doping rate of less than or equal to 10¹⁸/cm³.

Then, in step b), a layer which, according to the invention, has a specific thickness, namely a thickness of 1 to 10 nm, is deposited on the first main surface of the substrate. This layer is made of an electrically insulating metal or metalloid oxide, and this electrically insulating metal or metalloid oxide is a specific oxide, defined by a particular value of its dielectric constant which is, according to the invention, at least equal to 4, preferably at least equal to 6, even more preferably at least equal to 7, and better still at least equal to 25.

According to one fundamental characteristic of the method according to the invention, after the deposition of the electrically insulating metal or metalloid oxide layer, a step c) of annealing of this layer in a specific atmosphere, which is an oxygen atmosphere, is accomplished.

Such a step of annealing in such an atmosphere is neither described nor suggested in the prior art.

The method according to the invention, which comprises this specific sequence of specific steps, satisfies the needs, requirements and demands mentioned above, and provides a solution to the problems of the methods of the prior art.

In particular, the method according to the invention enables a gate to be obtained which enables the conductivity of a zone in a substrate made of an oxide of at least one n-type semiconducting metal to be inverted efficiently, reliably and reproducibly.

In addition, the gate obtained by the method according to the invention does not leak, i.e. it does not allow current to pass when a voltage is applied to it, with gate voltages which may be as high as 30 V. Using the method according to the invention, however, these gate voltages are not too high and do not generally exceed 30 V.

The method according to the invention enables inversion of conductivity in “large-gap” materials for which p-type doping cannot be implemented to be accomplished easily.

The method according to the invention obviates the need to dope these materials to obtain a p-type conductivity, and notably to produce LEDs, through a simple inversion of conductivity.

The doping rate of the substrate made of an oxide of at least one n-type semiconducting metal is advantageously 10¹³ to 10¹⁸/cm³.

The electrically insulating metal or metalloid oxide is advantageously chosen from among HfO₂ and ZrO₂.

The deposition of the electrically insulating metal or metalloid oxide layer is advantageously accomplished by an atomic layer deposition, or ALD, technique.

Deposition of the layer of electrically insulating metal or metalloid oxide is advantageously accomplished in a vacuum chamber with a pressure of less than 100 Torrs.

During the deposition of the electrically insulating metal or metalloid oxide layer, the temperature of the substrate is advantageously less than or equal to 450° C., and preferably the temperature of the substrate is of 50° C. to 450° C.

The annealing of the electrically insulating metal or metalloid oxide layer is advantageously accomplished over a period greater than or equal to 10 seconds, and preferably of 10 seconds to 15 minutes.

The annealing of the electrically insulating metal or metalloid oxide layer is advantageously accomplished at a temperature higher than or equal to 80° C., and preferably of 80° C. to 500° C.

The annealing is preferably accomplished at a temperature of 350° C., over a period of 5 minutes.

The electrically conductive material is advantageously a metal.

The metal is preferably chosen from among titanium, copper, platinum and gold.

Advantageously the thickness of the layer of an electrically conductive material such as a metal, or of each of the layers, when several layers are deposited, is generally of 0.5 to 300 nm, and preferably of 1 to 200 nm, for example 3 nm.

The small thicknesses enable semitransparent contacts to be obtained which allow 20 to 90% of the light to escape.

For example, a contact consisting of a 3 nm layer of Ti and a 3 nm layer of gold enables MIS structures to be produced whilst remaining almost transparent (approximately 10% of the emission absorbed in the visible spectrum).

During step d) a first primer layer, for example made of a first metal such as titanium, and a second anti-oxidation protective layer, for example, made of a second metal which does not oxidise, such as gold are thus preferably deposited in succession. Gold enables the Ti not to become oxidised.

The invention also relates to a method for manufacturing an optoelectronic device comprising a step during which a structure comprising a substrate made of at least one n-type semiconducting metal oxide, chosen from among ZnO, CdO, MgO, ZnMgO, and ZnCdO, wherein said substrate comprises a first main surface and a second main surface, wherein the first main surface of the substrate is covered with a layer made of an electrically insulating material, and the layer made of an electrically insulating material is covered with at least one layer made of an electrically conductive material is manufactured, by the method as described above.

Such a manufacturing method has all the advantages inherent to the method for manufacturing the structure which were listed above.

This optoelectronic device may notably be a light-emitting diode, or a field-effect transistor (MOSFET). The invention relates in particular to a method for manufacturing a light-emitting diode in which:
a structure comprising a substrate made of at least one n-type semiconducting metal oxide, chosen from among ZnO, CdO, MgO, ZnMgO, and ZnCdO, wherein said substrate comprises a first main surface and a second main surface, wherein the first main surface of the substrate is covered with a layer made of an electrically insulating material, and the layer made of an electrically insulating material is covered with at least one layer made of an electrically conductive material is manufactured, by the method as described above; and then
an electrical contact is formed on the second main surface of the substrate;
an electrical connection is formed with the layer made of an electrically conductive material;
an electrical connection is formed with the zone of the substrate the conductivity of which is inverted into a p-type conductivity, when a negative voltage is applied to the layer made of an electrically conductive material.

Here again, this method for manufacturing a light-emitting diode has all the advantages inherent to the method for manufacturing the structure which were listed above.

The invention will be better understood and other advantages of it will be better revealed on reading the detailed description which follows, given as an example, and not restrictively, and made with reference to the attached drawings.

### BRIEF DESCRIPTION OF THE DRAWINGS

FIG. 1 is a schematic vertical cross sectional view of a structure of the MIS type, manufactured by the method according to the invention, which enables the conductivity to be inverted in a portion of a substrate made of an oxide of at least one n-type semiconducting metal, such as a substrate made of n-type ZnO.

FIG. 2 is a schematic vertical cross sectional view which illustrates the inversion of conductivity obtained in a portion of the n-type substrate of the structure of FIG. 1 following application of a negative voltage to the metal deposit located at the top of the structure of FIG. 1.

FIG. 3 is a graph which shows the Curve C(V) of a structure according to the invention consisting of a gate deposited on a substrate made of n-type ZnO. The gate consists of a stack of a 3 nm layer of HfO₂, a 5 nm layer of titanium, and a 5 nm layer of gold on one face of the ZnO substrate. After deposition of the HfO₂, an annealing in O₂ at 450° C. is accomplished for 1 min. A contact consisting of a 50 nm layer of Ti and a 100 nm layer of gold is produced on the other face of the substrate to make the measurement.

FIG. 4 is a graph which shows the Curve C(V) of a structure according to the invention consisting of a gate deposited on a substrate made of n-type ZnO. The gate consists of a stack of a 10 nm layer of HfO₂, a 50 nm layer of titanium, and a 50 nm layer of gold on one face of the ZnO substrate. After deposition of the HfO₂, an annealing in O₂ at 450° C. is accomplished for 1 min. A contact consisting of a 50 nm layer of titanium and a 100 nm layer of gold is produced on the other face of the substrate to make the measurement.

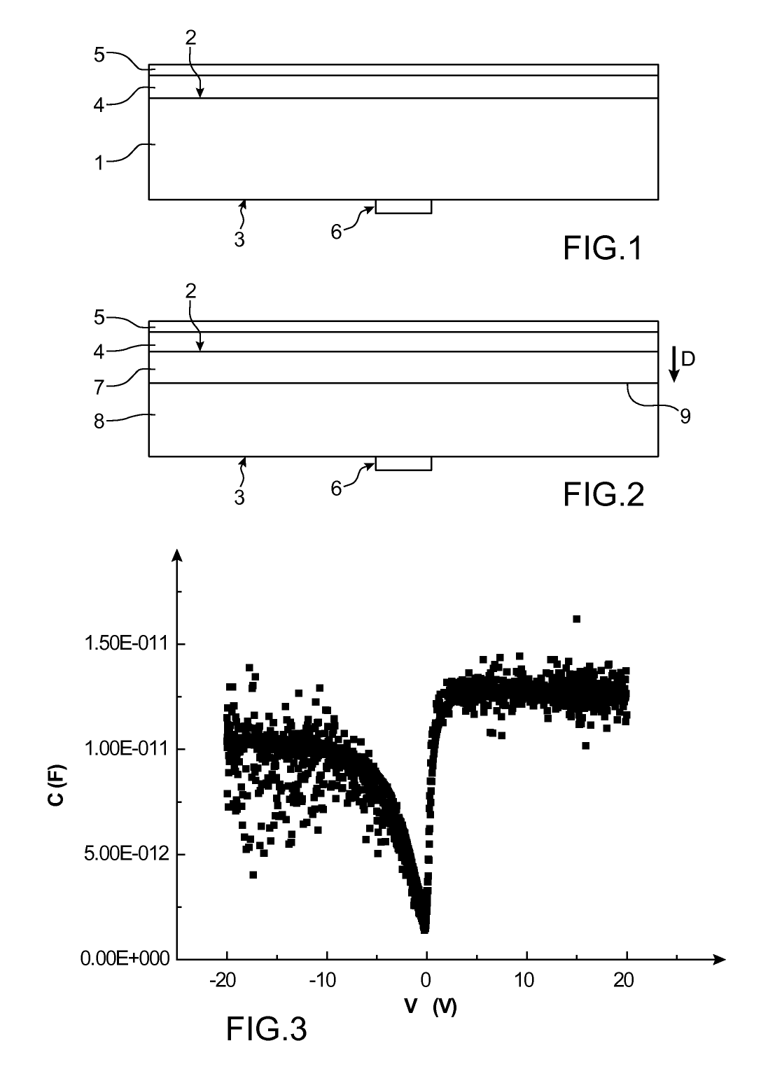

### DETAILED DESCRIPTION OF PARTICULAR EMBODIMENTS

In a first step of the method according to the invention, a substrate (1) is provided which is made of an oxide of at least one metal, where the said oxide of at least one metal is a semiconductor having n-type conductivity.

The said oxide of at least one metal may be chosen from among ZnO, CdO, MgO, ZnMgO and ZnCdO.

ZnMgO will preferably be chosen for an emission in the ultraviolet spectrum, and ZnCdO for an emission in the visible spectrum.

The description which follows will be made primarily with reference to the manufacture of a structure including a semiconducting substrate (1) made of ZnO, but those skilled in the art will easily be able to adapt to the teachings it contains to the manufacture of semiconducting structures made of other oxides such as CdO, MgO, ZnMgO and ZnCdO.

This substrate (1) includes a first main surface (2) and a second main surface (3).

The substrate (1) is generally a flat, planar substrate, i.e. the first (2) and the second (3) surfaces mentioned above are generally flat, preferably horizontal and parallel, and the first surface (2) is an upper surface, whereas the second surface (3) is a lower surface.

These surfaces may, for example, have the shape of a polygon such as a square or a rectangle, or again of a circle.

In addition, the thickness of the substrate (1) is generally small compared to the dimensions of the said first (2) and second (3) surfaces, such that in this case it can be considered that the substrate (1) takes the form of a layer.

The substrate (1) may be 10 nm to 1 mm thick, for example 0.5 mm to 1 mm thick, depending on the applications.

In the case of small thicknesses of less than or equal to 100 nm, for example 10 nm to 100 nm, the term “thin layer” will be used. The substrate (1) may in particular have the shape of a parallelepipedic rectangle with the abovementioned thickness, the dimensions of which are, for example, 5 nm to 1 cm in length, and 5 nm to 1 cm in width, or again it may have the shape of a square-section substrate of the abovementioned thickness, the side of which measures 5 nm to 1 cm.

Such ZnO substrates are available from the company Crystec® of Berlin, Germany, in sizes of 10×10 mm² or 10×5 mm², and thicknesses of 0.5 mm or 1 mm.

In accordance with the invention, ZnO has n-type conductivity, and the n-type doping rate of ZnO, i.e. the intrinsic donor concentration, is less than or equal to 10¹⁸/cm³.

Indeed, for a zone in ZnO to be successfully inverted there must not be too many charges to be pushed back into the ZnO.

This is the reason why the n-type doping rate of the ZnO constituting the substrate (1) is, according to the invention, less than or equal to 10¹⁸/cm³.

However, in order for the structure to be able to operate in an LED device, such as the one described in document [20], it is also preferable that the n-type doping of the ZnO should not be too low. For example, the n-type doping rate of the substrate may be greater than or equal to 10¹⁵/cm³.

The n-type doping rate of the ZnO is optimally 10¹⁵ to 10¹⁸/cm³.

A layer of an electrically insulating material (4) is then deposited on the first main surface (2) of the substrate (1).

According to the invention, this electrically insulating material is a specific insulating material which is chosen from among the metal or metalloid oxides.

The specific choice of an oxide to constitute the layer of an electrically insulating material (4) is matched with the final step of the method according to the invention during which annealing is accomplished in oxygen, precisely to improve the quality of this oxide.

Fundamentally, according to the invention, the electrically insulating material, chosen from among the electrically insulating metal or metalloid oxides, has a “high” dielectric constant k, i.e. a dielectric constant k which is at least equal to 4, preferably at least equal to 6, even more preferably at least equal to 7, and better still at least equal to 25.

In other words, this is a “high k” oxide with a dielectric constant greater than or equal to 4, preferably greater than or equal to 6, even more preferably greater than or equal to 7, and better still greater than or equal to 25.

Indeed, if the dielectric constant of the oxide is too low, a zone in the ZnO cannot successfully be inverted when this oxide is used as a gate oxide.

It has thus been shown that, when SiO₂, dielectric constant k of which is only 3.4, is used as a gate oxide, no zone in the ZnO can successfully be inverted.

Conversely, it has been shown that, when HfO₂ or ZrO₂, the dielectric constants k of which are of the order of 25, is used as a gate oxide, a zone in the ZnO can indeed successfully be inverted.

It appears that a dielectric constant k at least equal to 25 for the gate oxide is optimal to accomplish inversion in a zone in the ZnO.

Indeed, for values of the dielectric constant which are less than this optimal value, the gate thicknesses would have to be very, or excessively, small, for example less than one nm, and the gate voltages would have to be very high, for example higher than 30 V, to obtain an electrical field in the ZnO which is sufficient to invert a zone.

The deposition of the electrically insulating metal or metalloid oxide layer (4) is generally accomplished by an atom layer deposition, or ALD, technique.

The temperature of the substrate (1), during the deposition of the layer of electrically insulating metal or metalloid oxide, such as HfO₂ or ZrO₂, must generally be less than 450° C., in order for the electrically insulating metal or metalloid oxide, such as HfO₂ or ZrO₂, to be deposited correctly.

For the material to retain satisfactory dielectric properties, the temperature must also generally not be too low.

Typically, temperatures of the substrate (1) of between 50° C. and 450° C. can be used, for example a temperature of 150° C.

Deposition by ALD is accomplished within a chamber in which a primary or higher vacuum is present, i.e. a chamber in which a pressure of less than or equal to 100 Torrs is found.

Such a vacuum is required to obtain an electrically insulating metal or metalloid oxide, such as HfO₂ or ZrO₂, of satisfactory quality.

In particular, such a vacuum is important for the dielectric properties, and in particular a high dielectric coefficient, and also the satisfactory electric insulator properties of the electrically insulating metal or metalloid oxide, to be obtained.

An atomic layer deposition, ALD, cycle generally consists of 4 steps:

1) Exposure of the surface (i.e. of the first main surface (2)) of the substrate (1), which has been previously heated to the temperature mentioned above, to a precursor containing the metal or metalloid of the electrically insulating metal or metalloid oxide.

If this oxide is an oxide of hafnium or an oxide of zirconium the precursor will then contain respectively hafnium or zirconium.

These precursors are generally metal or metalloid organometallic compounds.

An example of a precursor containing hafnium is tetrakis(dimethylamido) hafnium IV, and an example of a precursor containing zirconium is tetrakis(dimethylamido) zirconium IV.

The duration of exposure of the surface of the substrate to the precursor must be sufficient to saturate the surface of the substrate with the precursor, for example with the precursor containing hafnium or zirconium.

2) Vacuum application step. During this step the substrate is held for a certain time in a vacuum, without exposing the surface of the substrate to the precursor.

This step enables the surplus molecules of the precursor to be given time to be desorbed from the surface of the substrate, and to be evacuated by pumping.

3) Exposure of the surface of the substrate to water.

This step enables the molecules of the precursor to be oxidised to form a monolayer or a fraction of a monolayer of an electrically insulating metal or metalloid oxide, for example HfO₂, or ZrO₂.

4) Vacuum application step. During this step the substrate and the oxide monolayer are held for a certain time in a vacuum, without exposing the surface of the substrate to water. This step enables the excess water molecules to be evacuated.

This cycle is generally repeated.

The residual pressure in the deposition chamber between two exposures of the surface to precursors or to water, i.e. during steps 2) and 4), is generally less than or equal to 100 Torr; typically this residual pressure is 10⁻³ to 100 Torrs.

The pressure during the pulses (i.e. during the steps of exposure to the precursor or to water) must rise again at least by 10% (relative to the said residual pressure) in the chamber.

The duration of the steps of exposure to a precursor (step 1)), or to water (step 2)), and of the steps of vacuum application (steps 3) and 4)), is generally longer than 0.05 s.

In order for the deposition method not to be of excessive length the duration of the steps of exposure to a precursor (step 1)) or to water (step 2)) is preferably 0.05 s to 1 s, for example 0.1 s, and the duration of the steps of vacuum application (steps 3) and 4)) is preferably 0.5 to 5 s, for example 2s.

1 to 1000 cycles may be accomplished, for example 100 cycles.

The number of cycles is chosen in order to obtain the desired thickness of the layer of electrically insulating metal or metalloid oxide (4), for example of HfO₂ or ZrO₂.

The thickness of the deposited electrically insulating metal or metalloid layer (4), for example of the layer of HfO₂ or ZrO₂, together with the annealing of this layer after deposition, as will be seen below, are very important to obtain gates which do not leak.

The thickness of the layer of electrically insulating metal or metalloid oxide (gate oxide) (4) must therefore be optimised.

If the thickness of this layer (4) is too small the leakage currents increase, despite an annealing being undertaken.

A zone in the substrate made, for example, of ZnO may, nevertheless, be inverted, but energy will be lost due to these leakage currents through the gate.

If this layer (4) is too thick excessively high gate voltages will be required to invert a zone in the substrate, for example made of ZnO.

It has been shown that the thickness of this layer (4) had generally to be 1 nm to 10 nm.

Indeed, above 10 nm the gate voltages are too high (i.e. generally over 30 V); whereas below this value the leakage currents cannot be limited.

A value of 3 nm is particularly preferred and is a satisfactory compromise.

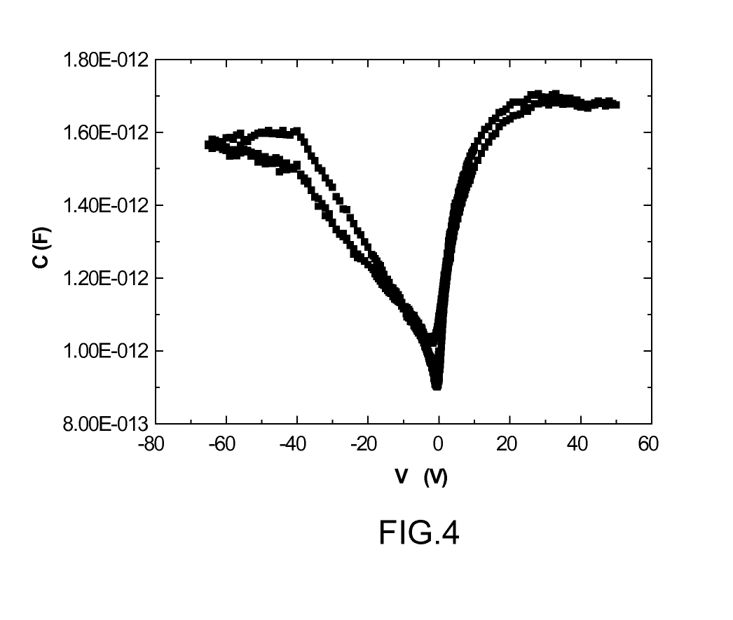

By choosing the thickness of the electrically insulating metal or metalloid oxide layer (4) within this range, a gate may be prepared which enables an inversion to be obtained in an n-type metal oxide, such as ZnO doped with an intrinsic donor concentration of less than 10¹⁸ cm⁻³ (this is shown by FIGS. 3 and 4).

To obtain an electrically insulating metal or metalloid oxide layer (4) 1 nm thick, 10 cycles must generally be accomplished, whereas to obtain an electrically insulating metal or metalloid oxide layer 10 nm thick, 100 cycles must generally be accomplished.

In accordance with the invention, an annealing of the deposited layer of electrically insulating metal or metalloid oxide (4), such as HfO₂ or ZrO₂, is then accomplished, under an oxygen atmosphere.

This annealing is generally accomplished over a period longer than 10 s, and at a temperature higher than 80° C.

The annealing is preferably accomplished for a period of 10 s to 15 minutes, at an annealing temperature of 80° C. to 500° C.

For example, the annealing may be accomplished at a temperature of 350° C., over a period of 5 minutes.

This annealing enables the properties of the electrically insulating metal or metalloid oxide to be greatly improved, and in particular its high-dielectric-constant dielectric properties, and its electrical insulator properties.

Indeed, annealing in oxygen seems to fill the oxygen vacancies which acted as a preferential path for conducting the current.

According to the invention, one or more layers of an electrically conductive material (5) are deposited on the electrically insulating metal or metalloid oxide layer (4).

The total deposited number of layers of electrically conductive material may range from 1 to 20.

If the structure is to be used in a light-emitting diode this electrically conductive material is preferably a material which is transparent to the light emitted by the diode, in order that it allows this light to pass through it.

This electrically conductive material is generally a metal.

The metal is preferably chosen from among titanium, copper, platinum and gold.

This layer (or these layers) of an electrically conductive material (5) may be deposited by any suitable deposition method. If this layer (5) is a metal layer, such as gold, it may thus be deposited by cathodic sputtering.

The thickness of the layer of an electrically conductive material (5), such as a metal, or of each of the layers, when several layers are deposited, is generally 0.5 to 300 nm, and preferably 1 to 200 nm.

In one embodiment, a stack of two metal layers is deposited on the layer of electrically insulating metal or metalloid oxide (4), such as ZrO₂ or HfO₂, to finalise the gate structure.

The first layer of this stack, which is deposited directly on the layer of electrically insulating metal or metalloid oxide, such as ZrO₂ or HfO₂, acts as a primer layer; it may be a layer of titanium, deposited for example by cathodic sputtering.

The second layer is generally a layer made of a metal which does not oxidise.

The role of this second layer is therefore primarily to protect the first metal layer of the stack, made for example of titanium, against oxidation.

The second layer of this stack deposited on the first layer may be a layer made of gold, deposited for example by cathodic sputtering.

The thickness of the first layer, made for example of titanium, and the thickness of the second layer, made for example of gold, of this stack, are generally greater than 0.5 nm, preferably 1 to 50 nm, for example 20 nm.

When a negative voltage is applied to the gate, or more precisely to the layer of an electrically conductive material (5) (through an electrical connection (not represented) with the layer (5)), relative to the potential of the substrate (1) imposed by an electrode or contact (6) formed on the second main surface of the substrate (1), an inversion of conductivity occurs (see FIG. 2) in a first zone (7) of the n-type substrate, adjacent to the electrically insulating metal or metalloid oxide layer (4), from the first main surface (2) of the substrate (1) and as far as a distance (D) in the substrate (1) from this first main surface (2). This first zone (7) therefore becomes a zone which has a p-type conductivity.

A second zone (8) of the substrate (1), further from the electrically insulating metal or metalloid oxide layer (4) and extending the from the distance (D) from the first main surface (2) as far as the second main layer (3), retains its initial n-type conductivity.

A “p/n pseudo-junction” (9) is thus created in the substrate (1).

The negative voltage applied to the gate is generally less than −3 V, notably less than −10 V, preferably −3 to −10 V, relative to the potential of the substrate (1), and this potential imposed on the substrate is generally 0 V.

Application of a voltage of −10 V to the gate enables a region of p-type conductivity (8) to be obtained under the electrically insulating metal or metalloid oxide layer (4), which may go as far as a distance D of 100 nm under the first main surface (2).

It has been found, by measurements of the capacity as a function of the voltage applied to a stack of substrate consisting of ZnO/Oxide such as HfO₂ or ZrO₂/metal, that inversion in ZnO could be achieved for voltages higher than 3 V, when the thickness of the HfO₂ or ZrO₂ oxide layer is 1 nm, for voltages higher than 10 V when the thickness of the HfO₂ or of ZrO₂ layer is 3 nm, and for voltages higher than 40 V when the thickness of the HfO₂ or ZrO₂ oxide layer is 10 nm (see examples 2 and 3).

Through the gate structure described above, i.e. formed of a stack of substrate consisting of ZnO/Oxide such as HfO₂ or ZrO₂/metal, surface resistances of 10⁹ Ω/cm² for an oxide thickness of 1 nm, 10¹¹ Ω/cm² for an oxide thickness of 3 nm and 10¹⁵ Ω/cm² for an oxide thickness of 10 nm have been measured.

This clearly demonstrates the satisfactory electrical resistivity of the oxides produced, and the importance of the annealing undertaken.

Before annealing, whatever the thickness of the oxide used, the surface resistances were less than 10⁶ Ω/cm² and it was impossible to obtain curves C(V) such as those shown in FIGS. 3 and 4 (see examples 2 and 3), proving that it is possible to invert a zone in the ZnO.

The structure according to the invention can be used in particular to manufacture a light-emitting diode.

In order to manufacture such a light-emitting diode,
a structure is first manufactured including a substrate made of an oxide of at least one n-type semiconducting metal, chosen from among ZnO, CdO, MgO, ZnMgO, and ZnCdO, where a first main surface of the substrate is covered with a layer of an electrically insulating material, and the layer of an electrically insulating material is covered with at least one layer of an electrically conductive material, by the method as described above; and then
an electrical contact or connection (6) is formed on the second main surface of the substrate (“n contact”);
an electrical connection is formed with the layer of an electrically conductive material (5);
an electrical connection or contact (“p contact”) is formed with the zone of the substrate the conductivity of which is inverted into a p-type conductivity, when a negative voltage is applied to the layer of an electrically conductive material (5).

When a negative voltage is applied to the gate, or rather to the layer of electrically conductive material (5), a “p/n pseudo-junction” (9) is created in the substrate (1), as described above.

By passing a current in the structure using the p contact and the n contact (contact (6)), holes can be injected in p-type region 7 and electrons injected in n-type region 8, and electroluminescence can be obtained. The lighting of the diode may be controlled through the voltage applied to the gate.

To increase the recombination efficiency, structures with quantum wells may be used. The depth of the inversion region may be controlled through the gate voltage, which can be adjusted so that the quantum well is located in the p/n junction, for example 5.

The method according to the invention for manufacturing a structure and a device such as an LED applies to many semiconductors, and in particular enables light to be emitted in the UV spectrum and the deep UV spectrum.

High light densities in the UV spectrum can be obtained, enabling screens to be manufactured.

The method according to the invention can be used in particular to manufacture white LEDs.

The method according to the invention in particular enables sources to be manufactured emitting in the deep UV spectrum, which are efficient around 200 nm for the disinfection of water by UV irradiation.

The invention will now be described with reference to the following examples, given as illustrations and non-restrictively.

### EXAMPLES

### Example 1

In this example an “MIS” structure, or more specifically a “MOS” structure, is manufactured by the method according to the invention.

During this method HfO₂ or of ZrO₂ is, in particular, deposited by a technique of atomic layer deposition, or ALS, on a commercial ZnO substrate provided by the company Crystec® (dimensions measuring 1 cm×1 cm×0.5 cm).

A Savannah S100® machine from Cambridge Nanotech® is used.

The procedure used is as follows.
Adjust the nitrogen flowmeters such that the basic pressure in the vacuum chamber of the machine between two pulses (i.e. two exposures to a precursor or to water) is of the order of 1 Torr, whereas the pressure during the pulses is of the order of 1.2 Torr. Heat the ZnO substrate to 150° C. in the chamber.

Choose a pulse duration of 0.1 s for the precursor containing hafnium, i.e. the tetrakis(dimethylamido) hafnium IV or the precursor containing zirconium, i.e. tetrakis(dimethylamido) zirconium IV, and also for the water.
Allow a time interval of 2 s between each pulse.
Accomplish 100 cycles to obtain a thickness of the order of 10 nm. This thickness may be adjusted by modifying the number of cycles.
Undertake an annealing in O₂ at 350° C. for 5 minutes.
Deposit 20 nm of titanium and 20 nm of gold by cathodic sputtering.

### Example 2

In this example an “MIS” structure, or more specifically a “MOS” structure, is manufactured by the method according to the invention.

This structure consists of a gate deposited on a ZnO substrate (doped at a rate of 10¹⁸ at/cm³). The gate consists of a stack on the ZnO of an HfO₂ layer 3 nm thick, of a titanium layer 5 nm thick, and of a gold layer 5 nm thick.

The HfO₂ layer is deposited by a technique of atomic layer deposition, ALD, under conditions comparable to those described in example 1, where the number of cycles (30) is adjusted to obtain the desired thickness of HfO₂, i.e. 3 nm.

The titanium and gold layers are deposited by cathodic sputtering.

After deposition of the HfO₂ layer an annealing is undertaken in oxygen at a temperature of 450° C. for one minute.

Finally, a titanium layer 50 nm thick, and a gold layer 100 nm thick are deposited on the other face of the substrate (facing the HfO₂ layer) to form by this means a contact in order to make capacity measurements as a function of the voltage.

The results of the measurements are shown in FIG. 3.

In this configuration, inversion is obtained when a negative voltage is applied to the gate, and is demonstrated by the fact that the capacity measured for the negative voltages rises again to values equivalent to those found for highly positive voltages.

It is observed that voltages of 10 V must be applied to attain inversion regime.

Through the gate structure of this example surface resistances of 10¹¹ Ω/cm² have been measured for a 3 nm oxide thickness.

This clearly demonstrates the satisfactory electrical resistivity of the oxide produced, and the importance of the annealing undertaken.

### Example 3

In this example an “MIS” structure, or more specifically a “MOS” structure, is manufactured by the method according to the invention.

This structure consists of a gate deposited on a ZnO substrate (doped at a rate of 10¹⁸ at/cm³). The gate consists of a stack on the ZnO of an HfO₂ layer 10 nm thick, of a titanium layer 50 nm thick, and of a gold layer 50 nm thick.

The HfO₂ layer is deposited by a technique of atomic layer deposition, ALD, under conditions comparable to those described in example 1, where the number of cycles (100) is adjusted to obtain the desired thickness of HfO₂, i.e. 3 nm.

The titanium and gold layers are deposited by cathodic sputtering.

After deposition of the HfO₂ layer an annealing is undertaken in oxygen at a temperature of 450° C. for one minute.

Finally, a titanium layer 50 nm thick, and a gold layer 100 nm thick are deposited on the other face of the substrate (facing the HfO₂ layer) to form by this means a contact in order to make capacity measurements as a function of the voltage.

The results of the measurements are shown in FIG. 4.

In this configuration, inversion is obtained when a negative voltage is applied to the gate, and is demonstrated by the fact that the capacity measured for the negative voltages rises again to values equivalent to those found for highly positive voltages. It is observed that voltages of 40 V must be applied to attain inversion regime.

Through the gate structure of this example surface resistances of 10¹⁵ Ω/cm² have been measured for a 10 nm oxide thickness.

This clearly demonstrates the satisfactory electrical resistivity of the oxide produced, and the importance of the annealing undertaken.

Before annealing, whatever the thickness of the oxide used, the surface resistances were less than 10⁶ Ω/cm² and it was impossible to obtain curves C(V) such as those shown in FIGS. 3 and 4, proving that it is possible to invert a zone in the ZnO.

### REFERENCES

[1] D. A. Steigerwald et al., IEEE J. Sel. Top. Quantum Electron. 8, 310 (2002).
[2] O. Brandt et al., Nat. Mater. 5, 769 (2006).
[3] Y. Taniyasu et al., Nature 441, 325 (2006).
[4] A. Khan et al., Nat. Photonics 2, 77 (2008).
[5] S. Nakamura et al., Jpn. J. Appl. Phys. 31, 1258 (1992).
[6] P. Kozodoy et al., J. Appl. Phys. 87, 1832 (2000).
[7] D. C. Look, “Doping and defects in ZnO bulk” in Thin Films and Nanostructures, C. Jagadish and S. J. Pearton, Eds. Oxford, U.K.: Elsevier, 2006.
[8] D. P. Norton et al., Mater. Today 7, 34 (2006).
[9] S. Choopun et al., Appl. Phys. Lett. 80, 1529 (2002).
[10] W. Yang et al., Appl. Phys. Lett. 78, 2787 (2001).
[11] D. C. Look et al., Appl. Phys. Lett. 85, 5269 (2004).
[12] A. Ashrafi et al., Jpn. J. Appl. Phys. 41, L1281 (2002).
[13] A. V. Singh et al., J. Appl. Phys. 93, 396 (2003).
[14] T. M. Barnes et al., Appl. Phys. Lett. 86, 112 (2005).
[15] A. Tsukazaki et al., Nat. Mater. 4, 42 (2005).
[16] Y. R. Ryu et al., Appl. Phys. Lett. 88, 241 (2006).
[17] J. H. Lim et al., Adv. Mater. 18, 2720 (2006).
[18] S. J. Jiao et al., Appl. Phys. Lett. 88, 031911 (2006).
[19] K. Ip et al., Appl. Phys. Lett. 85, 1169 (2004).
[20] EP-A1-2 149 919 & US-A1-2010/0025654
[21] WO-A1-2009/128777
[22] US-A1-2001/0006346
[23] US-A1-2008/0128760
[24] WO-A2-2006/105077
[25] WO-A2-2006/051995
[26] D. Gu, K. Tapily, P. Shrestha, M. Y. Zhu, G. Cellar, and H. Baumgart, Journal of The Electrochemical Society, 155 G129-G133 (2008).
[27] Diefeng Gu, Helmut Baumgart, Gon Namkoong, and Tarek M. Abdel-Fattah, Electrochemical and Solid-State Letters, 12 K25-K28 (2009).

What is claimed is:

1. A method for manufacturing a structure comprising a substrate made of at least one n-type semiconducting metal oxide selected from the group consisting of ZnO, CdO, MgO, ZnMgO, and ZnCdO, wherein said substrate comprises a first main surface and a second main surface, wherein the first main surface of the substrate is covered with a layer made of an electrically insulating material, and the layer made of an electrically insulating material is covered with at least one layer made of an electrically conductive material, the method comprising:
providing a substrate made of at least one n-type semiconducting metal oxide selected from the group consisting of ZnO, CdO, MgO, ZnMgO, and ZnCdO, wherein the doping rate of which is less than or equal to 10¹⁸/cm³;
depositing a layer which is 1 to 10 nm thick, made of an electrically insulating metal or metalloid oxide, having a dielectric constant which is at least equal to 4, on the first main surface of the substrate;
annealing the electrically insulating metal or metalloid oxide layer in an oxygen atmosphere; and
depositing at least one layer made of an electrically conductive material on the electrically insulating metal or metalloid oxide layer.

2. The method according to claim 1, wherein the doping rate of the substrate made of at least one n-type semiconducting metal oxide is 10¹³ to 10¹⁸/cm³.

3. The method according to claim 1, wherein the electrically insulating metal or metalloid oxide is selected from the group consisting of HfO₂ and ZrO₂.

4. The method according to claim 1, wherein the deposition of the electrically insulating metal or metalloid oxide layer is accomplished by an atom layer deposition (ALD) technique.

5. The method according to claim 4, wherein the deposition of the layer of electrically insulating metal or metalloid oxide is accomplished in a vacuum chamber with a pressure of less than 100 Torrs.

6. The method according to claim 4, wherein the temperature of the substrate, during the deposition of the electrically insulating metal or metalloid oxide, is less than or equal to 450° C.

7. The method according to claim 1, wherein the annealing of the electrically insulating metal or metalloid oxide layer is accomplished over a period greater than or equal to 10 seconds.

8. The method according to claim 1, wherein the annealing of the electrically insulating metal or metalloid oxide layer is accomplished at a temperature higher than or equal to 80° C.

9. The method according to claim 7, wherein the annealing is undertaken at a temperature of 350° C., for a period of 5 minutes.

10. The method according to claim 1, wherein the thickness of the layer of an electrically conductive material, or of each of the layers, when several layers are deposited, is 0.5 to 300 nm.

11. The method according to claim 1, wherein the electrically conductive material is a metal.

12. The method according to claim 11, wherein the metal is selected from the group consisting of titanium, copper, platinum and gold.

13. The method according to claim 1, wherein the depositing at least one layer made of an electrically conductive material on the electrically insulating metal or metalloid oxide layer forms a first primer layer and a second anti-oxidation protective layer deposited in succession.

14. The method for manufacturing an optoelectronic device comprising a step during which a structure comprising a substrate made of at least one n-type semiconducting metal oxide selected from the group consisting of ZnO, CdO, MgO, ZnMgO, and ZnCdO, wherein said substrate comprises a first main surface and a second main surface, wherein the first main surface of the substrate is covered with a layer made of an electrically insulating material, and the layer made of an electrically insulating material is covered with at least one layer made of an electrically conductive material is manufactured, by the method according to claim 1.

15. The method according to claim 14, wherein the said device is a light-emitting diode or a field-effect transistor.

16. The method for manufacturing a light-emitting diode wherein a structure comprising a substrate made of at least one n-type semiconducting metal oxide is selected from the group consisting of, chosen from among ZnO, CdO, MgO, ZnMgO, and ZnCdO, wherein said substrate comprises a first main surface and a second main surface, wherein the first main surface of the substrate is covered with a layer made of an electrically insulating material, and the layer made of an electrically insulating material is covered with at least one layer of an electrically conductive material is manufactured, by the method according to claim 1 wherein:
an electrical contact is formed on the second main surface of the substrate,
an electrical connection is formed with the layer made of an electrically conductive material, and
an electrical connection is formed with the zone of the substrate the conductivity of which is inverted into a p-type conductivity, when a negative voltage is applied to the layer made of an electrically conductive material.

17. The method according to claim 6, wherein the temperature of the substrate is above 50° C.

18. The method according to claim 7, wherein the annealing of the electrically insulating metal or metalloid oxide layer is accomplished over a period of less than 15 minutes.

19. The method according to claim 8, wherein the annealing of the electrically insulating metal or metalloid oxide layer is accomplished at a temperature lower than 500° C.

20. The method according to claim 13, wherein the first primer layer is made of titanium and the second anti-oxidation protective layer is made of a metal which does not oxidize.

21. The method according to claim 19, wherein the second anti-oxidation protective layer is made of gold.
